(19) United States
(12) Patent Application Publication
(10) Pub. No.: US 2003/0027422 A1
(43) Pub. Date: Feb. 6, 2003

(54) Method of locally forming metal silicide layers

(75) Inventors: Erh-Kun Lai, Taichung (TW); Hsin-Huei Chen, Miao-Li (TW); Ying-Tso Chen, Kaohsiung (TW); Shou-Wei Hwang, Chilung (TW); Yu-Ping Huang, Taichung (TW)

Correspondence Address: LOWE HAUPTMAN GILMAN & BERNER, LLP, 1700 Diagonal Road, Suite 310, Alexandria, VA, 22314, US

(73) Assignee: MACRONIX INTERNATIONAL CO., LTD.

(21) Appl. No.: 09/917,943

(22) Filed: Jul. 31, 2001

(51) Int. Cl. H01L 21/44; H01L 21/3205; H01L 21/4763

(52) U.S. Cl. 438/682; 438/655; 438/649; 438/651; 438/592

(57) ABSTRACT

The present invention mainly provides a method to locally form metal silicides on an integral circuit. The method can avoid forming metal silicides on the surface of those devices with high resistance, so the performance of those devices will not degrade. The method can also avoid a phenomenon of leakage current which is caused by forming metal silicide between the memory cells on the same word line.

The method of present invention achieve above objectives by principally forming a mask on those regions which don't need metal silicides on their surface. Afterward, a metal layer is deposited and a heating process of forming metal silicides is following. Therefore, all above objectives can be achieved.

### BACKGROUND

1. Field of the Invention

The present invention generally relates to a method of locally forming metal silicide layers, and in particular to a method of locally forming metal silicide layers which can avoid unwanted metal silicides be formed on the surface of a device with high resistance and can avoid a leakage current between memory cells caused by unwanted metal silicides.

2. Description of the Prior Art

In order to reduce the resistance and improve the performance of an integral circuit, a metal silicide layer, such as titanium silicide, is usually deposited on the surface of the integral circuit and elements thereon. But in some regions where the resistance have to be kept high, such as the spaced region between two neighboring memory cells on the same word line, or on the surface of some elements with high resistance, such as load transistors and electrostatic discharge (ESD) protection devices, the metal silicide layer should be avoided. A conventional method is shown in FIG. 1: first, a silicon substrate 100 is provided. There are at least two regions on the substrate 100: one is an array region 101, the other is a periphery region 102. In the array region 101, a dielectric layer 105, such as an oxide-nitride-oxide (ONO) layer, is deposited on the substrate 100. A memory array consisting of a plurality of memory cells 110 is formed on the dielectric layer 105, and a first spaced region 106 is existed between any two neighboring memory cells 110 on the same word line. In the periphery region 102, there are at least a plurality of transistors 120, and a second spaced region 107 is existed between any two neighboring transistors 120. After a process of forming metal silicides, the metal silicide layers (150,160,170) are formed on the top surface of the gates of the memory cells 110, the top surface of the gates of the transistors 120, and the surface of the silicon substrate 100.

However, in the prior method the process of forming the sidewall 130 of the gates of the memory cells 110 is hard to control, so an overetching phenomenon frequently occurs to expose a part of the substrate 100 within the first spaced region 206, as shown in FIG. 2A. Thus a metal silicide layer 240 is also formed on the surface of silicon substrate 100 within the first spaced region 206 when the process of forming metal silicide is carried out. As shown in FIG. 2B, the metal silicide layer 240 on the surface of silicon substrate 100 within the first spaced region 206 will cause the leakage current, and degrade the performance of the memory cells.

Besides, if there is any other element, such as a load transistor or a ESD protection device, formed on the silicon substrate 100, the metal silicide will be also formed on its surface, and this will cause some problems. We can see that all those unwanted problem are induced by a conventional method without selectivity of forming metal silicides.

### SUMMARY

It is an object of the invention to provide a method of locally forming metal silicide layers on a integral circuit.

It is another object of the invention to provide a method to avoid a leakage current caused by the formation of metal silicide layers between memory cells on the same word line.

It is a further object of the invention to provide a method to avoid forming metal silicides on the surface of those devices which need a high resistance.

According to the foregoing objects, the present invention provides a method comprising the following steps: first, a silicon substrate is provided. The silicon substrate can be divided into at least two regions: one is the array region, the other is the periphery region. In the array region, a first dielectric layer is deposited on the substrate, and a plurality of first transistors, such as a memory array, is formed on the first dielectric layer. A first spaced region is existed between any two neighboring transistors of the plurality of the first transistors. In the periphery region, a plurality of second transistors and a plurality of semiconductor devices are formed on the substrate, wherein the plurality of semiconductor devices are with high resistance, and a second spaced region is existed between any two neighboring transistors of the plurality of the second transistors. Afterward, a second dielectric layer is conformally deposited to cover the surface of the substrate, the array region, the plurality of the first transistors, the periphery region, the plurality of the second transistors, and the plurality of the semiconductor devices. A photoresist layer is then formed to cover the second dielectric layer. The part of the photoresist layer above those region where the metal silicides is unfavorable on its surfcace is removed. Such regions comprise the first spaced region, and the plurality of the semiconductor devices with high resistance. By using the remaining photoresist layer as a mask, another etching process is performed to remove a part of the second dielectric layer, so the remaining second dielectric layer is only existed in the first spaced region and on the surface of the plurality of the semiconductor devices with high resistance. Afterward, the remaining photoresist layer is also removed. Then, a metal layer is deposited to cover the overall surface of the structure. A heating process is then executed to form metal silicide. Finally, the metal layer and the remaining second dielectric layer are respectively removed.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 shows a schematic cross-sectional diagram of a conventional method of locally forming metal silicide layer on a integral circuit;

FIG. 2A to FIG. 2B show a series of schematic cross-sectional diagrams of an embodiment according to the conventional method in which an overetching phenomenon occurs;

FIG. 3A to FIG. 3J show a series of schematic cross-sectional diagrams of an embodiment according to the present method of locally forming metal silicide layers on an integral circuit.

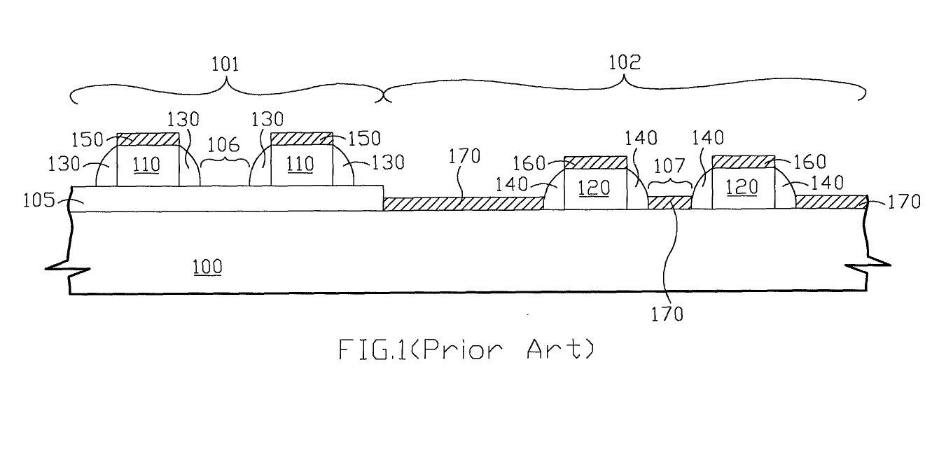

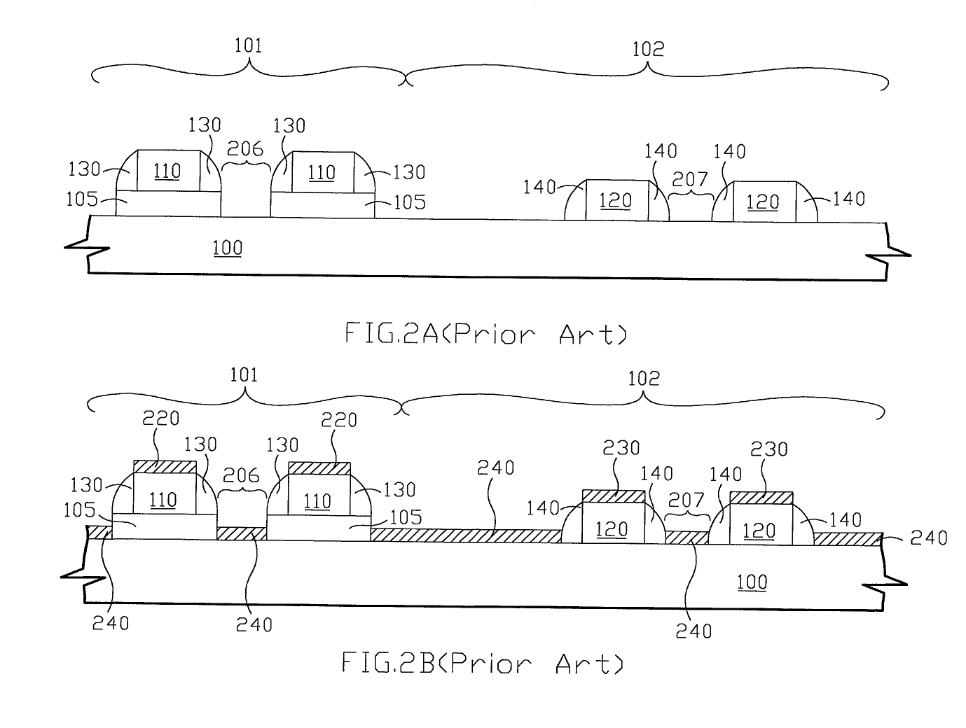

### DESCRIPTION OF THE PREFERRED EMBODIMENT

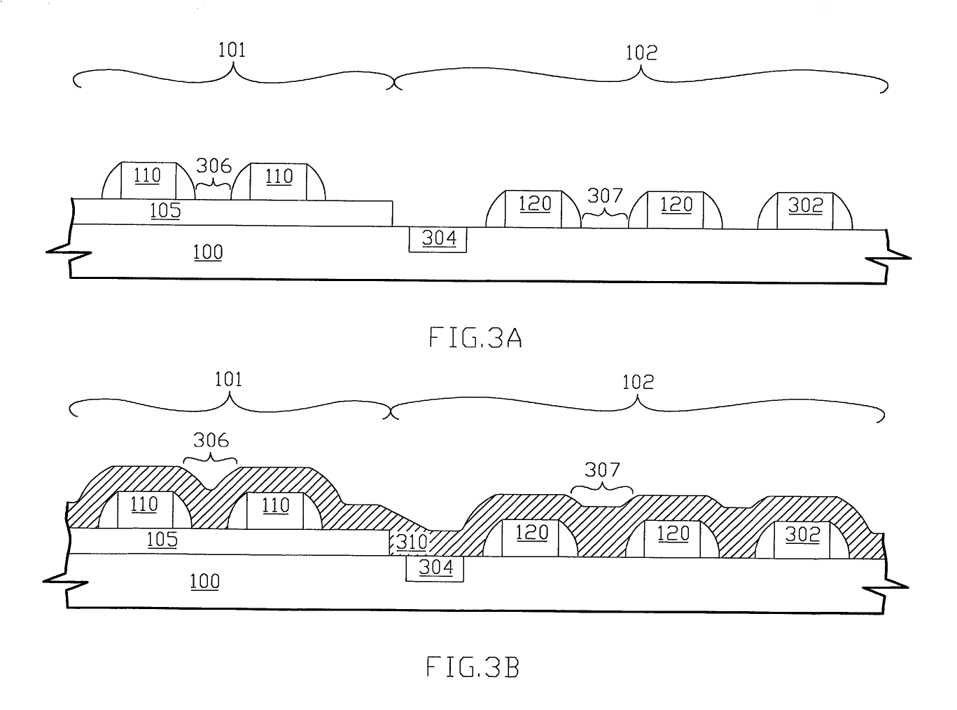

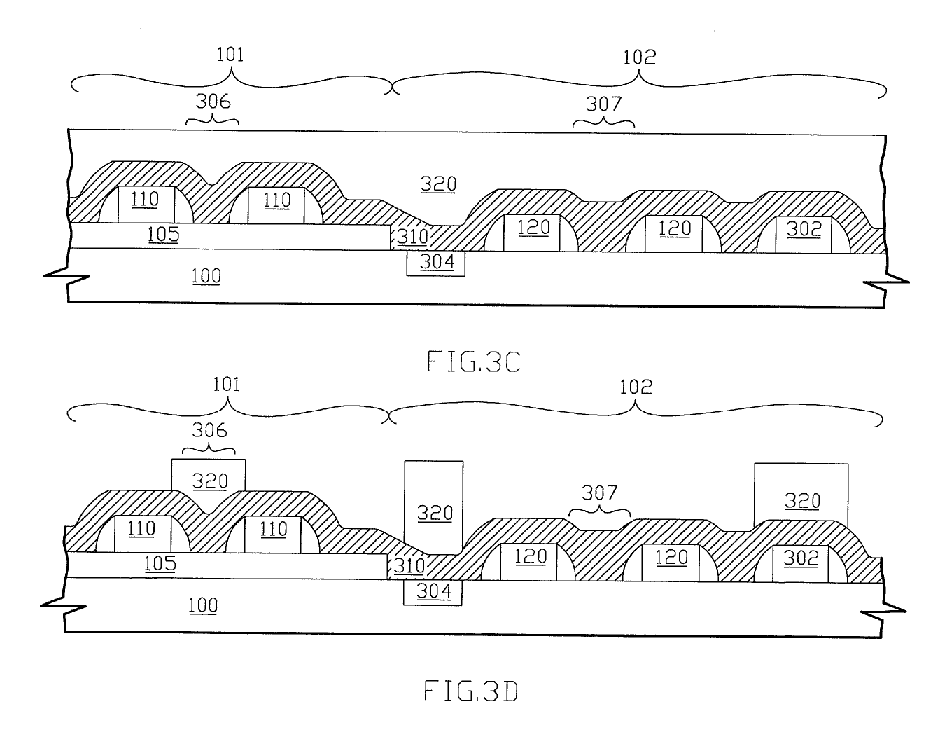

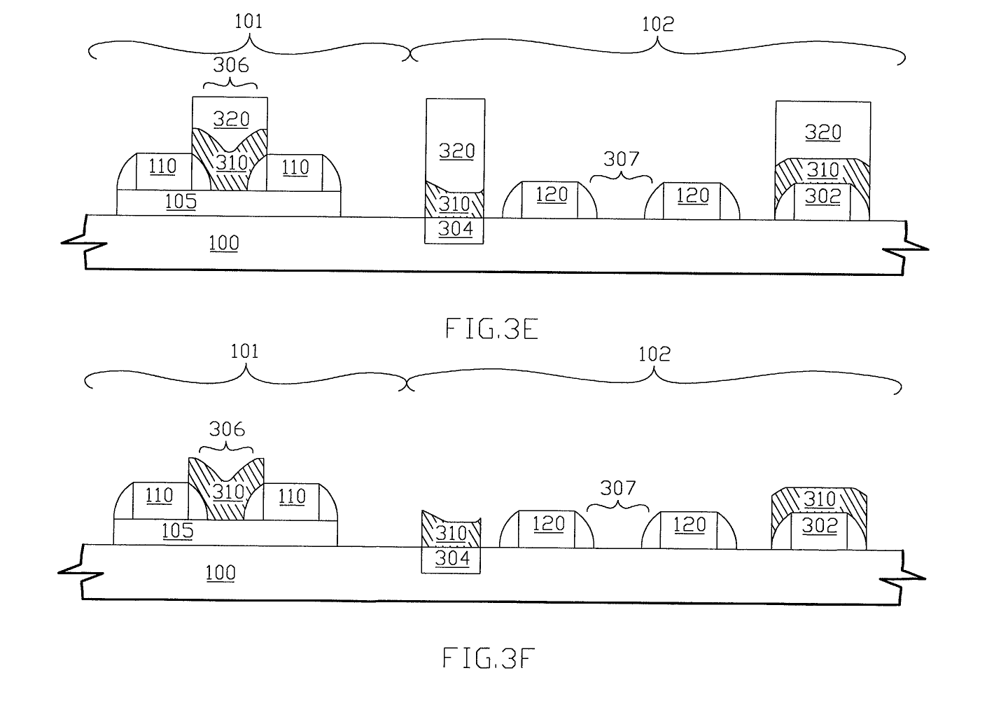

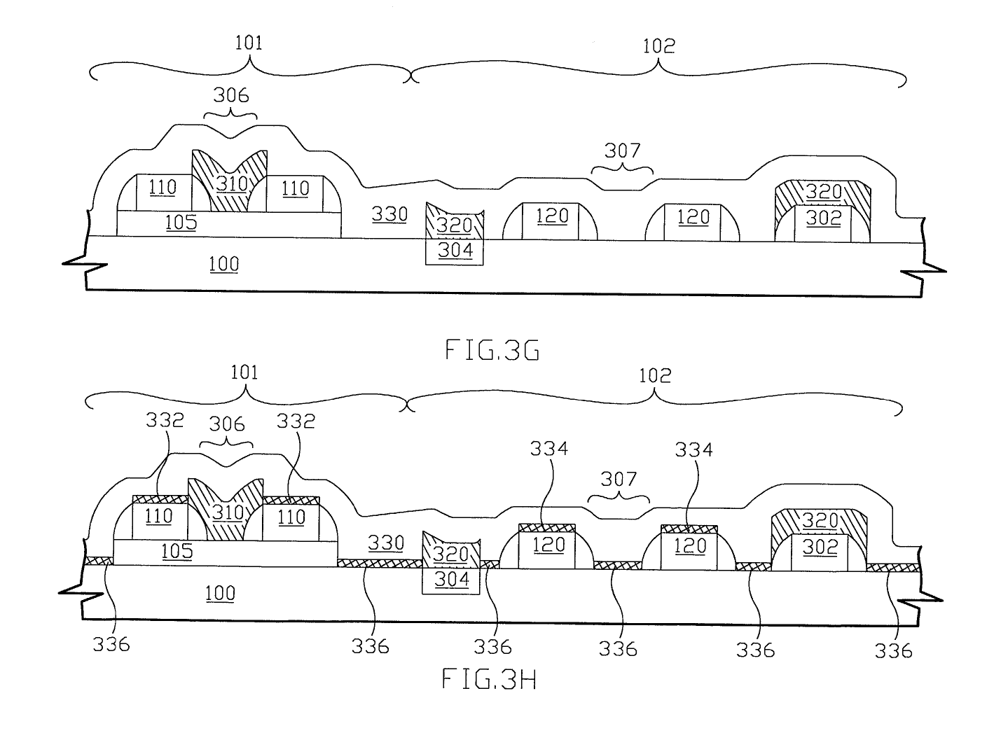

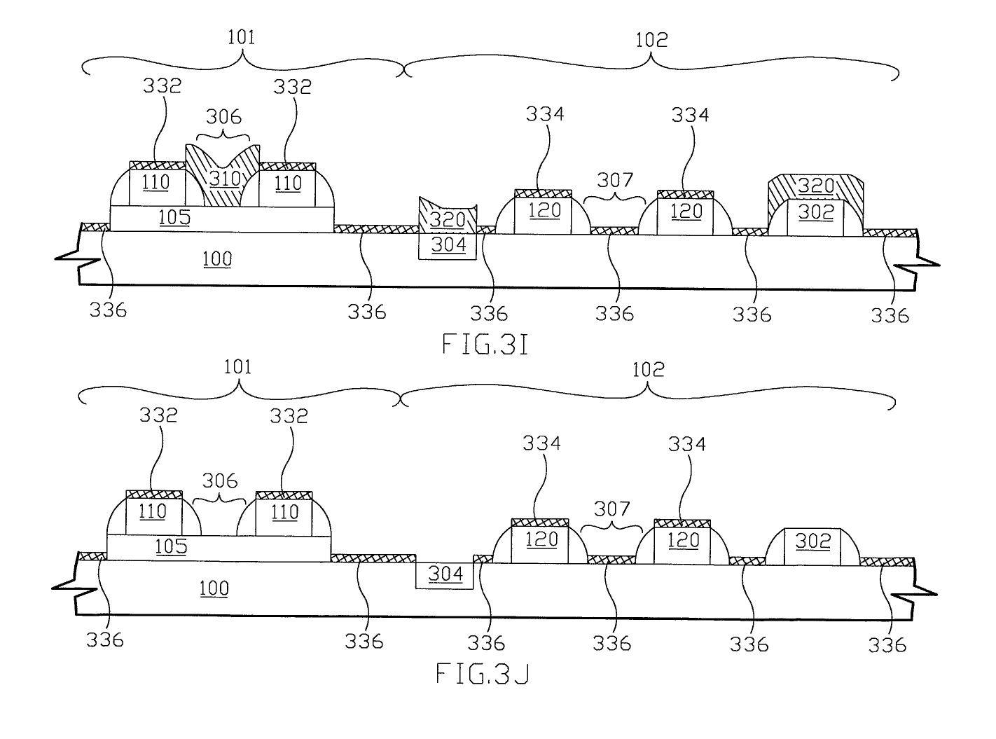

In present invention we provide a method of locally forming metal silicide layers on an integral circuit, wherein the method comprises the following steps: first, as shown in FIG. 3A, a substrate 100 is provided, and there are at least two regions on the substrate 100: one is the array region 101, the other is the periphery region 102. In the array region 101, an ONO layer is deposited on the substrate 100, and a memory array is formed on the ONO layer 105. And a first spaced region 306 is existed between any two neighboring memory cell 110 on the same word line. In the periphery region 102, there are at least two kinds of devices: one is a device which surface resistance would be reduced, such as a plurality of transistors 120; the other is a device which surface resistance would be kept high, such as a load transistor 302 and an electrostatic discharge (ESD) protection device304. And a second spaced region 307 is existed between any two neighboring transistors 120. In this embodiment, the distance of two gates of the memory cells 110 is about 0.36 micrometer as well as the distance of two gates of the transistors 120, and the width of the first spaced region 306 as well as that of the second spaced region 307 are about 0.34 micrometer.

Afterward, as shown in FIG. 3B, a dielectric layer 310, such as a silicon oxide layer or a silicon nitride layer, is conformally deposited to cover the overall surface of the array region 101 and the periphery region 102. The thickness of the dielectric layer is about 350 to about 500 angstrom. Afterward, a photoresist layer 320 is deposited to cover the dielectric layer 310, as shown in FIG. 3C. The photoresist layer 320 is then patterned and a part of the photoresist layer 320 is removed. The remaining photoresist layer is only on the first spaced region 306, the load transistor 302, and the ESD protection device 304, as shown in FIG. 3D. Afterward, by using the remaining photoresist layer 320 as a mask, an etching process is performed to remove most of the dielectric layer 310, and the residual part of the dielectric layer 310 is that shielded by the remaining photoresist layer 320, as shown in FIG. 3E. Then, the remaining photoresist layer 320 is removed, as shown in FIG. 3F.

Afterward, a metal layer 330, such as titanium, is deposited to cover the overall integral circuit, as shown in FIG. 3G. A heating process is then performed to make the metal react with the polysilicon to form metal silicide (332, 334, 336) on the surface of the gates of the memory cell 110, the gates of the transistors 120, and the silicon substrate 100, as shown in FIG. 3H. Because of the residual dielectric layer 310 no metal silicide is formed on the first spaced region 106, the load transistor 302, and the ESD protection device 304.

Afterward, the metal layer 330 is removed, as shown in FIG. 3I. Finally, the dielectric layer 310 is also removed, as shown in FIG. 3J, to expose the surface of the load transistor 302 and ESD protection device 304. As regards the part of dielectric layer 310 on the first spaced region 306, it can be preserved or removed, and which isn't a necessary step in our invention.

Therefore, the method of locally forming metal silicide is completed. In addition, the ONO layer 105 in the array region 101 can be replaced by other kind of dielectric layer. An oxide layer is further comprised between the gate 120 of transistor and the silicon substrate 100 and is used as a gate oxide layer.

Although specific embodiments have been illustrated and described, it will be obvious to those skilled in the art that various modifications may be made without departing from what is intended to be limited solely by the appended claims.

What is claimed is:

1. A method of locally forming metal silicide layers, said method comprising the steps of:
providing a silicon substrate, and said silicon substrate is divided into at least two regions: one is an array region, the other is a periphery region;
forming a first dielectric layer on said silicon substrate in said array region and a plurality of first transistors on said first dielectric layer, wherein there is a first spaced region between any two neighboring said first transistors;
forming a plurality of second transistors on said silicon substrate in said periphery region, wherein there is a second spaced region between any two neighboring said second transistors;
forming a plurality of semiconductor devices on said silicon substrate in said periphery region;
conformally depositing a second dielectric layer to cover said silicon substrate, said array region, said periphery region, said plurality of first transistors, said plurality of second transistors, and said plurality of semiconductor devices;
depositing a photoresist layer to cover said second dielectric layer;
removing a part of said photoresist layer above said first spaced region and said plurality of semiconductor devices;
performing an etching process to remove a part of said second dielectric layer by using said photoresist layer as a mask, and the remaining part of said second dielectric layer is above said first spaced region and said plurality of semiconductor devices;
removing said photoresist layer;
depositing a metal layer to cover said silicon substrate, said array region, said periphery region, said plurality of first transistors, said plurality of second transistors, and said second dielectric layer;
performing a heating process to form metal silicides;
removing said metal layer, and
removing said second dielectric layer.

2. The method according to claim 1, wherein said first dielectric layer is an oxide-nitride-oxide layer.

3. The method according to claim 1, said method further comprising a gate oxide between said silicon substrate and the gates of said plurality of second transistors.

4. The method according to claim 1, wherein said second dielectric layer is a silicon oxide layer.

5. The method according to claim 1, wherein said second dielectric layer is a silicon nitride layer.

6. The method according to claim 1, wherein said plurality of semiconductor devices are load transistors.

7. The method according to claim 1, wherein said plurality of semiconductor devices are electrostatic discharge protection devices.

8. The method according to claim 1, wherein said plurality of semiconductor devices comprise a load transistor and a electrostatic discharge protection device.

9. The method according to claim 1, wherein said metal layer is a titanium layer.

10. A method of locally forming metal silicide layers, said method comprising the steps of:
providing a silicon substrate, and said silicon substrate is divided into at least two regions: one is an array region, the other is a periphery region;
forming a first dielectric layer on said silicon substrate in said array region and a plurality of first transistors on said first dielectric layer, wherein there is a first spaced region between any two neighboring said first transistors;
forming a plurality of second transistors on said silicon substrate in said periphery region, wherein there is a second spaced region between any two neighboring said second transistors;
forming a plurality of load transistors on said silicon substrate in said periphery region;
forming a plurality of electrostatic discharge protection devices on said silicon substrate in said periphery region;
conformally depositing a second dielectric layer to cover said silicon substrate, said array region, said periphery region, said plurality of first transistors, said plurality of second transistors, said plurality of load transistors, and said plurality of electrostatic discharge protection devices;
depositing a photoresist layer to cover said second dielectric layer;
removing a part of said photoresist layer above said first spaced region, said plurality of load transistors, and said plurality of electrostatic discharge protection devices;
performing an etching process to remove a part of said second dielectric layer by using said photoresist layer as a mask, and the remaining part of said second dielectric layer is above said first spaced region, said plurality of load transistors, and said plurality of electrostatic discharge protection devices;
removing said photoresist layer;
depositing a metal layer to cover said silicon substrate, said array region, said periphery region, said plurality of first transistors, said plurality of second transistors, and said second dielectric layer;
performing a heating process to form metal silicides;
removing said metal layer, and
removing said second dielectric layer.

11. The method according to claim 10, wherein said first dielectric layer is an oxide-nitride-oxide layer.

12. The method according to claim 10, said method further comprising a gate oxide between said silicon substrate and the gates of said plurality of second transistors.

13. The method according to claim 10, wherein said second dielectric layer is a silicon oxide layer.

14. The method according to claim 10, wherein said second dielectric layer is a silicon nitride layer.

15. The method according to claim 10, wherein said metal layer is a titanium layer.
